(19) United States
(12) Patent Application Publication
(10) Pub. No.: US 2013/0040463 A1
(43) Pub. Date: Feb. 14, 2013

(54) METHOD AND APPARATUS FOR MANUFACTURING SEMICONDUCTOR DEVICE

(71) Applicant: Kenichi Oyama, Nirasaki City (JP)

(72) Inventor: Kenichi Oyama, Nirasaki City (JP)

(73) Assignee: TOKYO ELECTRON LIMITED, Tokyo (JP)

(21) Appl. No.: 13/580,069

(22) PCT Filed: Feb. 17, 2011
(86) PCT No.: PCT/JP2011/000887

§ 371 Date: Oct. 24, 2012

(30) Foreign Application Priority Data
Feb. 19, 2010 (JP) 2010-035295

(51) Int. Cl. H01L 21/311; G03B 27/32

(52) U.S. Cl. 438/702; 355/27; 257/E21.249

(57) ABSTRACT

A mask layer is formed by: a step in which a first photoresist layer is formed, exposed, and developed on a substrate, thereby forming a first photoresist pattern; a step in which the first photoresist pattern is made insoluble; a step in which a second photoresist layer is formed, exposed, and developed on top of the first photoresist layer, thereby forming a second photoresist pattern that intersects the first photoresist pattern; a step in which the second photoresist pattern is made insoluble; and a step in which a third photoresist layer is formed, exposed, and developed on top of the first and second photoresist patterns, thereby forming a third photoresist pattern.

### FIELD OF THE INVENTION

The present invention relates to a method and an apparatus for manufacturing a semiconductor device.

### BACKGROUND OF THE INVENTION

In a conventional semiconductor device manufacturing process, a fine circuit pattern is formed by a photolithography technique using a photoresist. Further, in order to further miniaturize the circuit pattern, a SWT (Side Wall Transfer) process, a DP (Double Patterning) process and the like have been examined.

As for a miniaturization technique in photolithography, there is known a technique in which a pattern of an initially formed photoresist is transferred to a hard mask to use the hard mask and a resist mask. However, in order to transfer the pattern to the hard mask, the hard mask needs to be formed and etched. This leads to an increase of the number of processes.

Therefore, there is known a technique for performing a lithography process twice in which a first photoresist pattern is formed and is subject to freeze (insolubilization process), and a second photoresist pattern is formed (coating, exposure and development of the photoresist), and then performing etching while using, as a mask, the double photoresist patterns obtained (see, e.g., Japanese Patent Application Publication No. 2008-306143).

In a conventional semiconductor manufacturing process, in order to form a fine hole at a desired location on a substrate, three steps are carried out. In a first step, a V-LINE is formed by first exposure. In a second step, an H-LINE perpendicular to the V-LINE is formed by second exposure. An orthogonal pattern obtained by the first and the second step is transferred to a hard mask. In a third step, a desired pattern for forming holes at desired locations is formed. By transferring this pattern to the hard mask, fine arbitrary holes are formed on the substrate.

The three steps are required because the resist pattern forming the desired pattern at the locations of fine arbitrary holes cannot be used in the second step.

### SUMMARY OF THE INVENTION

In view of the above, the present invention provides a method and an apparatus for manufacturing a semiconductor device, capable of improving productivity by omitting an initial step of transferring a pattern to a hard mask.

In accordance with an aspect of the present invention, there is provided a semiconductor device manufacturing method including forming a mask layer on an etching target layer formed on a substrate and etching the etching target layer while using the mask layer as a mask.

The method includes: forming a first photoresist layer on the substrate; forming a first photoresist pattern of holes arranged at a first pitch on the first photoresist layer; insolubilizing the first photoresist pattern; forming a second photoresist layer on the first photoresist pattern; and forming a second photoresist pattern having a second pitch wider than the first pitch on the second photoresist layer, thereby forming the mask layer.

In accordance with another aspect of the present invention, there is provided a semiconductor device manufacturing method including forming a mask layer on an etching target layer formed on a substrate and etching the etching target layer while using the mask layer as a mask.

The method includes: forming a first photoresist pattern by forming, exposing and developing a first photoresist layer on the substrate; insolubilizing the first photoresist pattern; forming a second photoresist pattern that intersects with the first photoresist pattern by forming, exposing and developing a second photoresist layer on top of the first photoresist layer; insolubilizing the second photoresist pattern; and forming a third photoresist pattern by forming, exposing and developing a third photoresist layer on top of the first and second photoresist patterns, thereby forming the mask layer.

In accordance with still another aspect of the present invention, there is provided a semiconductor device manufacturing method including: transferring a first parallel pattern to a photoresist coated on a substrate; transferring second parallel pattern perpendicular to the first parallel pattern to the photoresist; and transferring a pattern corresponding to holes of a third predetermined arbitrary pattern to the photoresist.

In accordance with still another aspect of the present invention, there is provided a semiconductor device manufacturing method including: transferring a first parallel pattern to a photoresist coated on a substrate; transferring a second parallel pattern parallel to the first parallel pattern to the photoresist; and transferring a pattern corresponding to holes of a third predetermined arbitrary pattern to the photoresist.

### EFFECT OF THE INVENTION

In accordance with the present invention, it is possible to provide a method and an apparatus for manufacturing a semiconductor device, capable of improving productivity by omitting an initial step of transferring a pattern to a hard mask.

The present invention can also provide a method and an apparatus for manufacturing a semiconductor device, capable of forming a fine pattern effectively by decreasing the number of processes and improving productivity compared to a prior art.

### BRIEF DESCRIPTION OF THE DRAWINGS

FIGS. 1A to 1G explain processes of a semiconductor device manufacturing method in accordance with an embodiment of the present invention.

FIG. 2 is a flowchart of the processes of the semiconductor device manufacturing method described in FIGS. 1A to 1G.

FIG. 3 is a top view showing a configuration of a semiconductor device manufacturing apparatus in accordance with an embodiment of the present invention.

FIG. 4 is a front view showing the configuration of the semiconductor device manufacturing apparatus shown in FIG. 3.

FIG. 5 is a rear view showing the configuration of the semiconductor device manufacturing apparatus shown in FIG. 3.

### DETAILED DESCRIPTION OF THE EMBODIMENTS

Hereinafter, the present invention will be described in detail with reference to the accompanying drawings which form a part hereof.

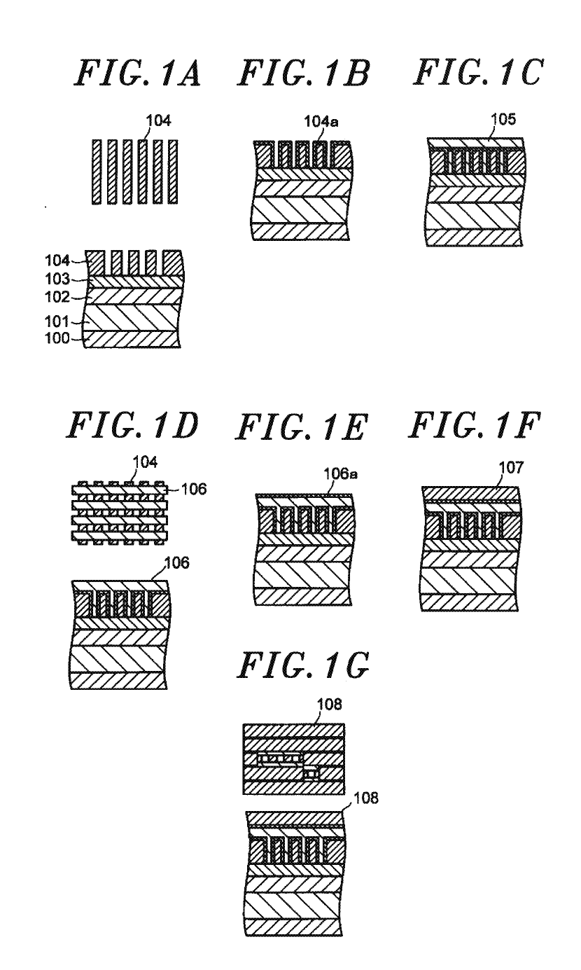

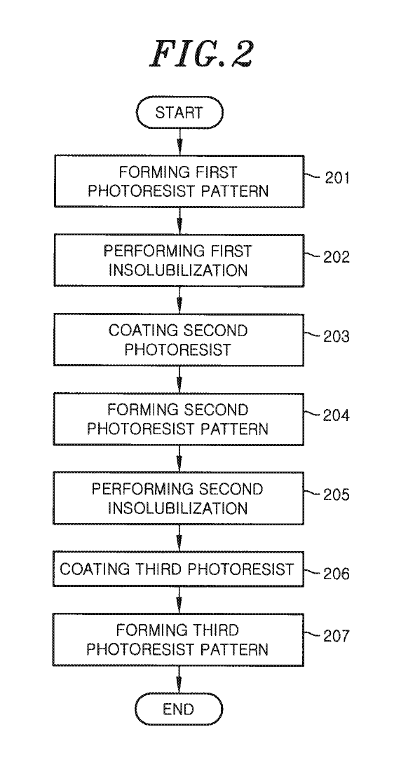

FIGS. 1A to 1G schematically show a part of a semiconductor wafer as a substrate in accordance with an embodiment of the present invention to explain processes of a semiconductor device manufacturing method in accordance with an embodiment of the present invention. FIG. 2 is a flowchart of the processes of the semiconductor device manufacturing method in accordance with the embodiment of the present invention.

As shown in FIG. 1A, an insulating film (e.g., a TEOS film) 101, a hard mask 102 and a bottom anti-reflection coating film 103 are formed in that order from the bottom on a semiconductor wafer 100. In the present embodiment, first, a photoresist is coated on the bottom anti-reflection coating film 103 and then subjected to exposure and development, thereby forming a first photoresist pattern 104 of a line-and-space-shape (step 201 in FIG. 2). The shape of the photoresist pattern 104 seen from the top is schematically shown in the upper side of FIG. 1A. The first photoresist pattern 104 has a line width in a range, e.g., from about 40 nm to 50 nm, and a pitch in a range, e.g., from about 80 nm to 100 nm (a half pitch in a range, e.g., from about 40 nm to 50 nm). The first photoresist pattern 104 can be formed by, e.g., ArF liquid immersion lithography or the like.

Next, as shown in FIG. 1B, a first insolubilization process (first freezing process) forming an insoluble layer 104a by insolubilizing the first photoresist pattern 104 is carried out (step 202 in FIG. 2). The first insolubilization process can be performed by, e.g., chemical freezing or the like.

Then, as shown in FIG. 1C, a second photoresist 105 is coated on the first photoresist pattern 104 (step 203 in FIG. 2).

Thereafter, as shown in FIG. 1D, a second photoresist pattern 106 of a line-and-space-shape is formed by performing exposure and development (step 204 in FIG. 2). As shown in the upper side of FIG. 1D, the first photoresist pattern 104 and the second photoresist pattern 106 intersects to be perpendicular to each other when seen from the top.

Next, as shown in FIG. 1E, a second insolubilization process (second freezing process) forming an insoluble layer 106a by insolubilizing the second photoresist pattern 106 is carried out (step 205 in FIG. 2). The second insolubilization process can be performed by, e.g., chemical freezing or the like.

As shown in FIG. 1F, a third photoresist 107 is coated on the first photoresist pattern 104 and the second photoresist pattern 106 (step 206 in FIG. 2).

Then, as shown in FIG. 1G, a third photoresist pattern 108 is formed by performing exposure and development (step 207 in FIG. 2). Further, as shown in the upper side of FIG. 1G, the third photoresist pattern 108 has an arbitrary pattern and has a wider pitch compared to the first and the second photoresist pattern 104 and 106 when seen from the top.

By performing the above processes, a mask having a pattern in which contact holes arranged at a narrow pitch and arbitrary-shaped holes arranged at a wider pitch than that of the contact holes are mixed can be formed. The lower bottom anti-reflection coating film 103, the hard mask 102 and the insulating film (e.g., TEOS film) 101 are etched by using this mask. Accordingly, holes are formed in the insulating film 101.

As described above, in the present embodiment, without transferring a pattern onto the hard mask first and forming the mask of the photoresist on the hard mask, the contact holes densely arranged at a line width of about 40 nm to 50 nm and a pitch of about 80 nm to 100 nm (half pitch of about 40 nm to 50 nm) and a two-dimensional pattern formed at a pitch of about 160 nm to 200 nm wider than that of the contact holes can be transferred at one time by using a mask formed of three-layer photoresist patterns. Therefore, a fine pattern can be effectively formed by decreasing the number of processes and the productivity can be improved compared to the prior art.

The first photoresist pattern 104 has a line-and-space shape having a pitch of about 80 nm to 100 nm, and the second photoresist pattern 106 has a line-and-space shape perpendicular to the first photoresist pattern and having the same pitch as that of the first photoresist pattern.

Thus, contact holes densely arranged at a pitch of about 80 nm to 100 nm can be formed without precise alignment. Thereafter, only predetermined contact holes among the densely arranged contact holes remain by a third photoresist pattern having a pitch of about 160 nm to 200 nm which is wider than those of the first and the second photoresist pattern. Accordingly, contact holes of a predetermined shape can be formed by simply exposing two patterns having a minimum pitch and the pattern having a wider pitch three times in total without using minimum resolution for all patterns.

In other words, in order to form the contact holes densely arranged at the pitch of about 80 nm to 100 nm, the pattern needs to be divided multiple times. When the second resist pattern formed of holes arranged between the holes arranged in the first photoresist pattern is exposed for example, the precise alignment is required and there is high possibility in which the positions of the holes are misaligned.

Meanwhile, when the holes are formed by intersecting line-and-space-shaped patterns at right angles as in the present embodiment, contact holes arranged at a dense pitch can be formed without precise alignment. By increasing the pitch of the third photoresist pattern compared to that of the first and the second photoresist patterns as in the present embodiment, the present invention can achieve the technique capable of selectively forming contact holes of the first and the second photoresist patterns, the contact holes overlapping with holes of the third photoresist pattern by overlapping these patterns without precise alignment.

In the present embodiment, the first and the second photoresist pattern 104 and 106 have the line-and-space shape having the same pitch and perpendicular to each other. However, the pitch may be different, and the patterns may not be perpendicular to each other. Moreover, in a process for forming a densely aligned hole pattern, a densely aligned hole-shaped pattern can be used. In that case, a photoresist pattern formed of densely arranged holes is formed by a single exposure and development process instead of intersecting line-and-space-shaped patterns as in the present embodiment. Then, an arbitrary hole pattern can be formed by the same sequences as the present embodiment.

Hereinafter, the embodiment of a semiconductor device manufacturing apparatus for performing the above-described semiconductor device manufacturing method will be described.

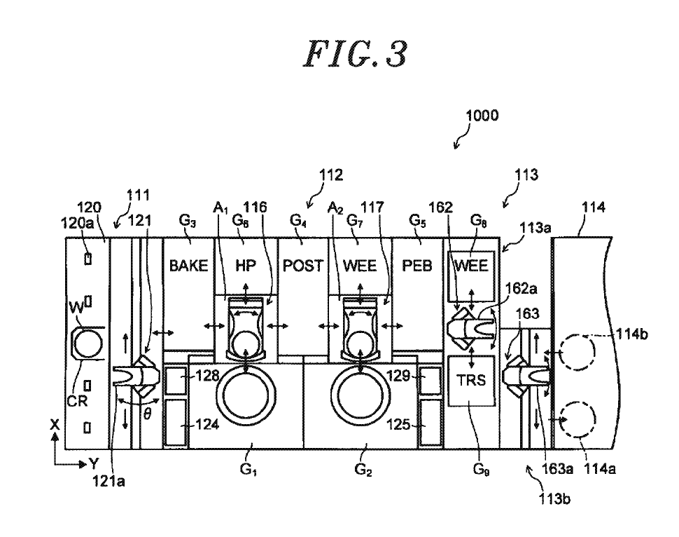

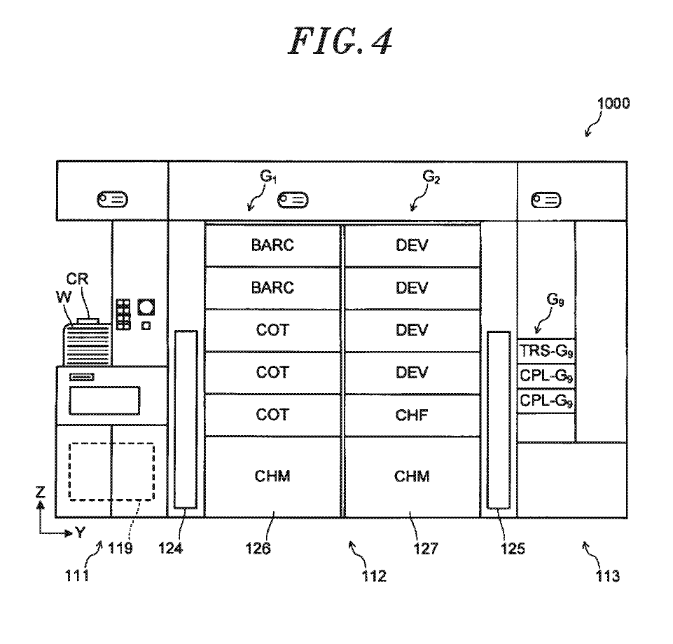

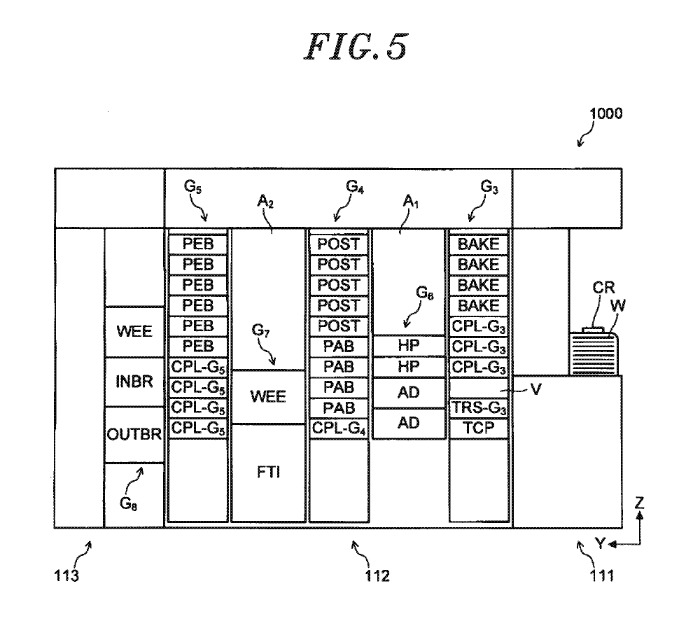

FIGS. 3 to 5 schematically show a configuration of a resist coating/developing system of a semiconductor device manufacturing apparatus in accordance with the present embodiment. FIG. 3 is a top view; FIG. 4 is a front view; and FIG. 5 is a rear view. A resist coating/developing system 1000 includes: a cassette station 111; a processing station 112 having a plurality of processing units; and an interface station 113 for transferring a wafer W between the processing station 112 and an exposure device 114 provided adjacent to the processing station 112.

A wafer cassette CR where a plurality of semiconductor wafers W to be processed by the resist coating/developing system 1000 is horizontally accommodated is loaded into the cassette station 111 from another system. Further, a wafer cassette CR where a plurality of semiconductor wafers W processed by the resist coating/developing system 1000 is accommodated is unloaded from the cassette station 111 and loaded into another system. Further, the cassette station 111 transfers the semiconductor wafers W between the wafer cassette CR and the processing station 112.

As shown in FIG. 3, a cassette mounting table 120 extending along the X direction is provided at an end portion of an inlet side of the cassette station 111 (end portion in the Y direction in FIG. 3). A plurality of (five in FIG. 3) positioning protrusions 120a is mounted in one row on the cassette table 120 along the X direction, and the wafer cassettes CR is mounted on the protrusions 120a with e wafer loading/unloading port facing the processing station 112.

In the cassette station 111, a wafer transfer unit 121 is positioned between the cassette mounting table 120 and the processing station 112. The wafer transfer unit 121 has wafer transfer picks 121a capable of moving in the cassette arrangement direction (X direction) and the arrangement direction of the semiconductor wafers W in the wafer cassette CR (Z direction). The wafer transfer picks 121a can rotate in the θ direction shown in FIG. 3. Accordingly, the wafer transfer picks 121a can access any of the wafer cassettes CR and also can access a transition unit TRS-G₃ in a third processing unit group G₃ of the processing station 112 which will be described later.

In the processing station 112, a first and a second processing unit group G₁ and G₂ are provided at a front side of the system in that order from the cassette station 111 side. Further, a third to a fifth processing unit group G₃ to G₅ are provided at a rear side of the system in that order from the cassette station 111 side. A first main transfer unit A₁ is disposed between the third processing unit group G₃ and the fourth processing unit group G₄, and a second main transfer unit A₂ is disposed between the fourth processing unit group G₄ and the fifth processing unit group G₅. A sixth processing unit group G₆ is provided at a bottom surface side of the first main transfer unit A₁, and a seventh processing unit group G₇ is provided at a bottom surface side of the second main transfer unit A₂.

As shown in FIGS. 3 and 4, five spinner processing units serving as liquid supply units for performing predetermined treatment on semiconductor wafers W mounted on a spin chuck in a cup are laminated in the first processing unit group G₁. The five spinner processing units include, e.g., three photoresist coating units (COT) and two coating units (BARC) for forming a bottom anti-reflection coating film for preventing reflection of light during the exposure. In the second processing unit group G2, five spinner processing units, e.g., a chemical freezing unit (CHF) for performing chemical freezing as the insolubilization process and four developing units (DEV) are laminated.

As shown in FIG. 5, in the third processing unit group G3, a temperature control unit (TCP), a transition unit (TRS-G₃) serving as a transfer unit for transferring a semiconductor wafer W between the cassette station 111 and the first main transfer unit A₁, a spare space V where a desired oven-type processing unit and the like can be installed, three high-precision temperature control units (CPL-G₃) for performing heat treatment on a semiconductor wafer W under a precisely controlled temperature management, and four high-temperature heat treatment units (BAKE) for performing predetermined heat treatment on a semiconductor wafer W are laminated at ten stages from the bottom.

In the fourth processing unit group G₄, a high-precision temperature control unit (CPL-G₄), four pre-bake units (PAB) for performing heat treatment on a semiconductor wafer W after resist coating, and five post-bake units (POST) for performing heat treatment on a semiconductor wafer W after development are laminated at ten stages from the bottom.

In the fifth processing unit group G₅, four high-precision temperature control units (CPL-G₅), and six post exposure bake units (PEE) for performing heat treatment on a semiconductor wafer W before development and after exposure are laminated at ten stages from the bottom.

The high-temperature heat treatment unit (BAKE), the pre-bake unit (PAB), the post-bake unit (POST), and the post-exposure bake unit (PEB) which are provided at the third to the fifth processing unit group G₃ to G₅ have the same structure, for example, to form a heat treatment unit.

The laminated number and the arrangement of the third to the fifth processing unit group G₃ to G₅ may be set arbitrarily without being limited to the illustrated ones.

In the sixth processing unit group G₆, two adhesion units (AD) and two heating units (HP) for heating a semiconductor wafer W are laminated at four stages from the bottom.

In the seventh processing unit group G₇, a film thickness measuring unit (FTI) for measuring a resist film thickness and a peripheral exposure unit (WEE) for selectively exposing an edge portion of a semiconductor wafer W are laminated at two stages from the bottom.

As shown in FIG. 3, the first main transfer unit A₁ is provided with a first main wafer transfer unit 116, which can selectively access each unit of the first, the third, the fourth and the sixth processing unit groups G₁, G₃, G₄ and G₆.

The second main transfer unit A₂ is provided with a second main wafer transfer unit 117, which can selectively access each unit of the second, the fourth, the fifth and the seventh processing unit groups G₂, G₄, G₅ and G₇.

In the first and the second main wafer transfer device 116 and 117, three arms for supporting the semiconductor wafer W are laminated in a vertical direction. Further, the semiconductor wafer W supported by the arms can be transferred in any of the X direction, Y direction, Z direction and e direction.

As shown in FIG. 3, a liquid temperature control pump 124 and a duct 128 are provided between the first processing unit group G₁ and the cassette station 111, and a liquid temperature control pump 125 and a duct 129 are provided between the second processing unit group G₂ and the interface station 113. The liquid temperature control pumps 124 and 125 supply predetermined processing liquid to the first and the second processing unit group G₁ and G₂, respectively. The ducts 128 and 129 supply pure air supplied from an air controller (not shown) provided outside the resist coating/developing system 1000 into the processing unit groups G₁ to G₅.

The first to the seventh processing unit groups G₁ to G₇ can be detached for maintenance, and a panel provided at the rear surface side of the processing station 112 can be detached or opened/closed. As shown in FIG. 4, chemical units CHM 126 and 127 for supplying predetermined processing liquid to the first and the second processing unit groups G₁ and G₂ are provided below the first and the second processing unit groups G₁ and G₂.

The interface station 113 includes a first interface station 113a of the processing station 112 side and a second interface station 113b of the exposure device 114 side. In the first interface station 113a, a first wafer transfer body 162 is provided so as to face the opening of the fifth processing unit group G₅. In the second interface station 113b, a second wafer transfer body 163 capable of moving in the X direction is provided.

As shown in FIG. 5, an eighth processing unit group in which an OUT buffer cassette (OUTBR) for temporarily accommodating semiconductor wafers W unloaded from the exposure device 114, an IN buffer cassette (INBR) for temporarily accommodating semiconductor wafers W transferred to the exposure device 114 and a peripheral exposure devices (WEE) are laminated in that order from the bottom is provided on the rear surface side of the first wafer transfer body 162. The IN buffer cassette INBR and the OUT buffer cassette OUTBR can accommodate a plurality of, e.g., 25 semiconductor wafers W.

As shown in FIG. 4, a ninth processing unit group G₉ in which two-stage high-precision temperature control units (CPL-G₉) and a transition unit (TRS-G₉) are laminated in that order from the bottom is provided on the front surface side of the first wafer transfer body 162.

As shown in FIG. 3, the first wafer transfer body 162 has wafer transfer forks 162a capable of moving in the Z direction, rotating in the 8 direction and moving back and forth on the X-Y plane. The forks 162a can selectively access each unit of the fifth, the eighth and the ninth processing unit group G₅, G₈, and G₉, and thus can transfer the semiconductor wafers W therebetween.

In the same manner, the second wafer transfer body 163 has wafer transfer forks 163a capable of moving in the X and Y direction, rotating in the 9 direction and moving back and forth on the X-Y plane. The forks 163a can selectively access each unit in the ninth processing unit group G₉ and an IN stage 114a and an OUT stage 114b of the exposure device 114, and thus can transfer the semiconductor wafers W therebetween.

As shown in FIG. 4, a centralized control unit 119 for controlling the entire resist coating/developing system 1000 is provided at a lower portion of the cassette station 111. The centralized control unit 119 includes a process controller having a CPU for controlling each component, such as units, transfer units and the like, in the resist coating/developing system 1000, a user interface having a keyboard, a display or the like, and a storage unit for storing control programs, recipes, various databases and the like.

The following is description on the processes for forming the first to the third resist patterns by using the resist coating/developing system 1000 configured as described above.

First, unprocessed semiconductor wafers W are unloaded from the wafer cassette CR one at a time by the wafer transfer unit 121 and then transferred to the transition unit (TRS-G₃) of the processing unit group G₃ of the processing station 112.

Next, the temperature control unit TCP performs a temperature control process on the semiconductor wafer W. Thereafter, the bottom anti-reflection coating film is formed by the coating unit (BARC) in the first processing unit group G₁; the heat treatment is performed by the heating unit (HP); and the bake process is performed by the high-temperature heat treatment unit (BAKE). The adhesion process may be performed by the adhesion unit (AD) before the bottom anti-reflection coating film is formed on the semiconductor wafer W by the coating unit (BARC).

Then, the temperature of the semiconductor wafer W is controlled by the high precision temperature control unit (CPL-G₄). Next, the semiconductor wafer W is transferred to the resist coating unit (COT) of the first processing unit group G₁, and the coating of the photoresist is carried out.

Next, the prebake unit (PAB) in the fourth processing unit group G₄ performs a pre-bake process on the semiconductor wafer W, and the peripheral exposure process is performed by the peripheral exposure device (WEE). Thereafter, the temperature control is performed by the high precision temperature control unit (CPL-G₉) or the like. Then, the semiconductor wafer W is transferred into the exposure device 114 by the second wafer transfer body 163.

The semiconductor wafer W subjected to the exposure process by the exposure device 114 is loaded into the transition unit (TRS-G₉) by the second wafer transfer body 163. Next, the temperature control process is performed on the semiconductor wafer W. The temperature control process includes a post exposure bake process performed by the post exposure bake unit (PEB) in the fifth processing unit group G₅, a development process performed by the development unit (DEV) in the second processing unit group G₂, a post bake process performed by the post bake unit (POST), or the like.

By performing the above-described sequences, the first photoresist pattern is patterned. Next, the semiconductor wafer W is transferred to the chemical freezing unit (CHF) in the second processing unit group G₂ so as to be subjected to an insolubilization process.

Thereafter, a second photoresist pattern is formed by repeating the sequences from the photoresist coating process performed by the resist coating unit (COT) to the insolubilization process performed by the chemical freezing unit (CHF). Further, the third photoresist pattern is formed by repeating the sequences from the photoresist coating process performed by the resist coating unit (COT) to the temperature control process such as the post bake process performed by the post bake unit (POST) or the like. The etching is performed while using as a mask the first to the third photoresist patterns.

While the invention has been shown and described with respect to the embodiments, the present invention can be variously modified without being limited to the above-described embodiments.

### INDUSTRIAL APPLICABILITY

The present invention can be used in a semiconductor device manufacturing field or the like. Thus, the present invention has an industrial applicability.

1-3. (canceled)

4. A semiconductor device manufacturing method including forming a mask layer on an etching target layer formed on a substrate and etching the etching target layer while using the mask layer as a mask, the method comprising:
forming a first photoresist pattern by forming, exposing and developing a first photoresist layer on the substrate;
insolubilizing the first photoresist pattern;
forming a second photoresist pattern that intersects with the first photoresist pattern by forming, exposing and developing a second photoresist layer on top of the first photoresist layer;
insolubilizing the second photoresist pattern; and
forming a third photoresist pattern by forming, exposing and developing a third photoresist layer on top of the first and second photoresist patterns, thereby forming the mask layer.

5. The semiconductor device manufacturing method of claim 4, wherein a pattern of holes arranged at a first pitch is formed by said forming the first photoresist pattern and said forming the second photoresist pattern; and
a pattern having a second pitch wider than the first pitch is formed by said forming the third photoresist pattern.

6. The semiconductor device manufacturing method of claim 5, wherein the first pitch is about 80 nm to 100 nm, and the second pitch is about 160 nm to 200 nm.

7. A semiconductor device manufacturing method comprising:
transferring a first parallel pattern to a first photoresist coated on a substrate;
transferring second parallel pattern perpendicular to the first parallel pattern to a second photoresist; and
transferring a pattern corresponding to holes of a third predetermined arbitrary pattern to a third photoresist.

8. The semiconductor device manufacturing method of claim 7, wherein a pitch of the first parallel pattern is about 80 nm to 100 nm; and a pitch of the second parallel pattern is about 80 nm to 100 nm; and a pitch of the third predetermined arbitrary pattern is about 160 nm to 200 nm.

9. The semiconductor device manufacturing method of claim 7, wherein a pitch of the third predetermined arbitrary pattern is greater than that of the first parallel pattern and that of the second parallel pattern.

10. The semiconductor device manufacturing method of claim 7, wherein the holes of the third predetermined arbitrary pattern are perfect circles or ovals.

11. A semiconductor device manufacturing method comprising:
transferring a first parallel pattern to a first photoresist coated on a substrate;
transferring a second parallel pattern intersecting with the first parallel pattern to a second photoresist; and
transferring a pattern corresponding to holes of a third predetermined arbitrary pattern to a third photoresist.

12. The semiconductor device manufacturing method of claim 11, wherein a pitch of the third predetermined arbitrary pattern is greater than that of the first parallel pattern and that of the second parallel pattern.

13. The semiconductor device manufacturing method of claim 12, wherein the pitch of the first parallel pattern is about 80 nm to 100 nm; and the pitch of the second parallel pattern is about 80 nm to 100 nm; and the pitch of the third predetermined arbitrary pattern is about 160 nm to 200 nm.

14. The semiconductor device manufacturing method of claim 11, wherein the holes of the third predetermined arbitrary pattern are perfect circles or ovals.

15. A semiconductor device manufacturing apparatus configured to perform the semiconductor device manufacturing method described in claim 4, the apparatus comprising:
a unit for forming a photoresist layer on a substrate;
a unit for exposing the photoresist layer;
a unit for developing the exposed photoresist layer; and
a unit for insolubilizing the developed photoresist layer.

16. The semiconductor device manufacturing method of claim 12, wherein the holes of the third predetermined arbitrary pattern are perfect circles or ovals.

17. The semiconductor device manufacturing method of claim 13, wherein the holes of the third predetermined arbitrary pattern are perfect circles or ovals.

18. A semiconductor device manufacturing apparatus configured to perform the semiconductor device manufacturing method described in claim 7, the apparatus comprising:
a unit for forming a photoresist layer on a substrate;
a unit for exposing the photoresist layer;
a unit for developing the exposed photoresist layer; and
a unit for insolubilizing the developed photoresist layer.

19. A semiconductor device manufacturing apparatus configured to perform the semiconductor device manufacturing method described in claim 11, the apparatus comprising:
a unit for forming a photoresist layer on a substrate;
a unit for exposing the photoresist layer;
a unit for developing the exposed photoresist layer; and
a unit for insolubilizing the developed photoresist layer.
